(19) United States
(12) Patent Application Publication
(10) Pub. No.: US 2010/0272951 A1
(43) Pub. Date: Oct. 28, 2010

(54) TWIN-FREE SINGLE CRYSTAL NOBLE-METAL NANO WIRE AND FABRICATION METHOD OF TWIN-FREE SINGLE CRYSTAL NOBLE-METAL NANO WIRE

(75) Inventors: Bongsoo KIM, Daejeon (KR); Sol HAN, Daejeon (KR)

Correspondence Address: CANTOR COLBURN, LLP, 20 Church Street, 22nd Floor, Hartford, CT, 06103, US

(73) Assignee: KOREA ADVANCED INSTITUTE OF SCIENCE AND TECHNOLOGY, Daejeon (KR)

(21) Appl. No.: 12/617,374

(22) Filed: Nov. 12, 2009

(30) Foreign Application Priority Data
Apr. 23, 2009 (KR) 10-2009-0035522
Jun. 18, 2009 (KR) 10-2009-0054414

(51) Int. Cl. C30B 23/00; C22C 5/06; B32B 7/00

(52) U.S. Cl. 428/119; 117/88; 420/501

(57) ABSTRACT

Provided is a fabrication method of a noble metal nanowire. More specifically, provided is a fabrication method of a noble metal nanowire, wherein the noble metal nanowire having an epitaxial relation with a single crystal substrate is fabricated on the single crystal substrate using noble metal halide as a precursor by placing the precursor in a front portion of a reactor and the single crystal substrate in a rear portion of the reactor and performing heat treatment in a condition that an inert gas flows from the front portion of the reactor to the rear portion of the reactor under a predetermined pressure, wherein a major axial direction of the noble metal nanowire with respect to a surface of the single crystal substrate is controlled by controlling a temperature of the precursor.

### CROSS-REFERENCE(S) TO RELATED APPLICATIONS

The present invention claims priority of Korean Patent Application No. 10-2009-0035522 filed on Apr. 23, 2009 and Korean Patent Application No. 10-2009-0054414 filed on Jun. 18, 2009 which is incorporated herein by reference.

### BACKGROUND OF THE INVENTION

1. Field of the Invention

The present invention relates to a single crystalline noble metal nanowire with no 2-dimensional defect including twin and a fabrication method of a single crystalline noble metal nanowire with no 2-dimensional defect on a substrate by a vapor-phase transport process, and more particularly, to a fabrication method of high quality 2-dimensional defect-free noble metal nanowire by controlling a temperature of the precursor and a control method of orientation of a major axis of the noble metal nanowire.

2. Description of Related Art

In general, a noble metal single crystalline nanowire has high chemical stability, high thermal conductivity and electric conductivity and is highly useful in electrical, magnetic and optical devices and sensors.

Ag has the highest electric and thermal conductivities among all metals, and shows the highest efficiency in Surface Enhanced Raman Scattering (SERS) in the range of visible rays due to optical property of Ag. Fabrication of this Ag in the form of a nanowire is expected to develop in various applications from a micro electronic device to an optical sensor. Particularly in the SERS, since an intensity of a signal largely depends on a fine shape of the Ag nanostructure, it is most important for fabrication of definite chemical or bio sensor to fabricate a nanowire with a clean surface which is defined and analyzed well.

The SERS phenomenon can be observed also in Au, like in Ag. In general, a metal nanostructure can absorb molecules on a surface thereof using Self-Assembled Monolayer (SAM), and it is possible to obtain a molecular layer uniformly absorbed on a surface of an Au nanostructure using this phenomenon. Utilization as a selective bio molecule analysis and an optical device can be largely practiced by observing the SERS phenomenon of molecules using the Au nanowire and SAM and applying molecules forming SAM as a linker. Also, use of the Au nanowire structure in the SERS measurement is expected to be utilized as a very high sensitive analysis technology.

Pd is getting attention in utilization as a sensor. Development of various precise gas sensors is yet remained as an important challenge in a field requiring high precision with development of science and technology. Also, development of a sensor having excellent detection ability is far off not only in domestic developing teams but also in foreign developing teams In particular, development of a highly sensitive hydrogen gas sensor for a fuel cell capable of monitoring leakage of hydrogen generable upon commercialization of the fuel cell together with development of the fuel cell is remained as a challenge which should be carried out parallel with study for the fuel cell to be used as next generation clean energy. What is considered as important as such development of the hydrogen sensor is to develop a material to be used as the sensor. One of the materials which is getting attention most is metal Pd, and studies for synthesizing a nanowire using the metal Pd which shows strong adsorptive capacity for the hydrogen and absorbs the hydrogen 900 times the volume of Pd itself and applying the synthesized nanowire as a highly sensitive sensor are in progress in various domestic and foreign groups.

Pt has characteristics of unique catalytic activity, prevention of oxidation and corrosion at high temperature and high melting point, and is widely used in industries due to these characteristics. Pt is widely used in automotive, chemical and oil industries and becomes an important industrial metal due to characteristic as an excellent catalyst, and is used in a contact portion and an electrode in a thermal battery and various electric and electronic applications due to chemical inactivity and thermal stability. Also, Pt has become more important as Pt is recently used as an electrode in commercial utilization of a fuel cell which converting chemical energy into electric energy. The SERS phenomenon can be observed also in Pt, like in Ag.

Since a noble metal single crystalline nanowire has no defect within the crystal as compared to a nanowire consisting of polycrystals, surface Plasmon transfer on the surface of the nanowire is excellent. Therefore, the noble metal single crystalline nanowire shows, unlike the noble metal polycrystal nanowire, a characteristic usable as a surface plasmon resonator through measurement of light signal scattered at both ends of the nanowire.

In order to utilize the aforementioned noble metal nanowire, development of technology capable of fabricating a noble metal single crystalline nanowire having high purity and no internal defect and defined well at an atomic level and a noble metal single crystalline nanowire physically separated from each other without using a catalyst or a template and being present individually is urgently required.

The present applicant has filed a method for fabricating a noble metal nanowire having high purity and crystallinity not using a catalyst and a template but using a vapor phase transport process (Korean patent application publication No. 2009-0001004) and a method for fabricating an noble metal nanowire having orientation with respect to a surface of a substrate (Korean patent application publication No. 2009-0004456).

The Korean patent application publication No. 2009-0004456 provides a method for fabricating noble metal nanowire having vertical or horizontal relation with a substrate surface by using flow rate and pressure as main control parameters among temperature and pressure of a precursor, temperature of the substrate, flow rate of an inert gas that affect the orientation of the nanowire, and further provides a method for fabricating noble metal nanowire having vertical or horizontal relation with a substrate surface using noble metal material or noble metal oxide as the precursor.

Although the Korean patent application publication No. 2009-0004456 discloses use of noble metal halide as the precursor, the present applicant have found that it is difficult to control the orientation of noble metal nanowire using the noble metal halide as the precursor by the method disclosed in the Korean patent application publication No. 2009-0004456 since vaporization characteristics of the noble metal material and the noble metal oxide are different from that of the noble metal halide, and developed the present invention.

Furthermore, the present applicant has been deeply studied for the fabrication of the nanowire and the control of orientation thereof by a vapor-phase transport process and developed the present invention as the result, providing an another technology capable of synthesizing Ag nanowire having an orientation with respect to a substrate.

### SUMMARY OF THE INVENTION

An embodiment of the present invention is directed to providing a fabrication method of a noble metal nanowire not using a catalyst and a template but using noble metal halide as a precursor, of which orientation with respect to a substrate (orientation between a major axis of the nanowire and a surface of the substrate) is controlled by controlling a temperature of the precursor. Another object of the present invention is to provide a pt nanowire with high purity and high crystallinity and having an epitaxial relation with the substrate surface.

Another embodiment of the present invention is directed to providing a fabrication method of a single crystalline Ag nanowire, having no defect including twin and high crystallinity, high purity and a crystallographically well defined surface, without use of an organic/inorganic template provided with nanopores, and a mass-producible and reproducible fabrication method of an Ag nanowire.

Further another embodiment of the present invention is directed to providing a single crystalline Ag nanowire with high crystallinity, high purity and a controlled shape, and having a predetermined orientation with respect to a substrate.

Hereinafter, the present invention will be described in detail. Unless defined otherwise, all technical and scientific terms used herein have the same meanings as commonly understood by one of ordinary skill in the art to which the present invention belongs.

Hereinafter a first aspect of a fabrication method of a noble metal nanowire in accordance with the present invention will be described in detail.

The present invention provides a fabrication method of a noble metal nanowire, wherein the noble metal nanowire having an epitaxial relation with a single crystalline substrate is fabricated on the single crystalline substrate using noble metal halide as a precursor by placing the precursor in a front portion of a reactor and the single crystalline substrate in a rear portion of the reactor and performing heat treatment in a condition that an inert gas flows from the front portion of the reactor to the rear portion of the reactor under a predetermined pressure, wherein a major axial direction of the noble metal nanowire with respect to a surface of the single crystalline substrate is controlled by controlling a temperature of the precursor.

The noble metal halide is preferably noble metal chloride, noble metal bromide, noble metal iodide or noble metal fluoride, and more preferably noble metal chloride.

Specifically, the noble metal halide is a compound in which noble metal of Au, Ag, Pd, Pt, Ir, Os, Ru or Rh is bonded with F, Cl, I or Br, and the noble metal halide includes noble metal halide hydrate. Au, Ag, Pd, Pt, Ir, Os, Ru or Rh single crystalline nanowire is fabricated using the noble metal halide as a precursor, and is fabricated by controlling a temperature of the precursor so that a major axis of the nanowire has an orientation vertical or horizontal to the surface of the single crystalline substrate.

The orientation of the major axis of the noble metal nanowire to the substrate surface is characterized in that one or more noble metal nanowire formed on the substrate has the same orientation. More specifically, a plurality of noble metal seeds having the same epitaxial relation with the substrate surface and the noble metal seeds are grown under control of material supply mechanism of material supplied to the noble metal seeds, thereby fabricating a plurality of noble metal nanowires having the same orientation.

In accordance of the present invention, the noble metal nanowire having an orientation vertical or horizontal to the substrate surface is fabricated using a temperature of the precursor as a main control parameter among the temperature of the precursor, a pressure, a temperature of the substrate, a flow rate of an inert gas that affect the orientation of the nanowire.

As thermal decomposition and thermal vaporization of the noble metal halide are very easy, the temperature is maintained at a high temperature, specifically 0.9 to 1.1 atm, in order to precisely control the direction of the major axis (growth direction) of the noble metal nanowire by controlling the temperature of the precursor.

As the thermal decomposition and the thermal vaporization of the noble metal halide are very easy, the inert gas flows at a high flow rate, specifically 200 to 300 sccm, in order to precisely control the direction of the major axis (growth direction) of the noble metal nanowire by controlling the temperature of the precursor.

The temperature of the substrate is a temperature providing driving forces for nucleation and growth of the noble metal material and allowing easy mass transport (mass transport including surface diffusion, vapor phase diffusion and diffusion inside the crystal) and is specifically 0.4 to 0.95 Tm (Tm: melting point (° C.) of the noble metal material of the noble metal nanowire to be fabricated).

By controlling the temperature of the precursor or the noble metal halide under the aforementioned pressure, flow rate of the inert gas and temperature of the substrate, a vertical noble metal nanowire having an epitaxial relation with the substrate and grown in a direction vertical to the substrate and a horizontal noble metal nanowire having an epitaxial relation with the substrate and grown in a direction horizontal to the substrate are selectively fabricated on the substrate.

The temperature of the precursor is 0.6 to 0.9 times the lower temperature between a melting point (° C.) and a decomposition point (° C.) of the precursor. By this control of the precursor temperature, the vertical noble metal nanowire having the major axial direction vertical to the surface of the substrate is fabricated.

The temperature of the precursor is 1.3 to 1.6 times the lower temperature between the melting point (° C.) and the decomposition point (° C.) of the precursor. By this control of the precursor temperature, the horizontal noble metal nanowire having the major axial direction horizontal to the surface of the substrate is fabricated.

The substrate is preferably a substrate epitaxial to the noble metal material for the noble metal nanowire to be fabricated, and more preferably a single crystalline substrate in which a low index plane including a family of {111} plane, a family of {110} plane and a family of {100} plane and a crystal plane on the substrate surface are epitaxial to each other.

More specifically, the single crystalline substrate is a surface of a nonconductive or semiconductive single crystal in which nucleation, particularly a 2-dimensional nucleation of a target noble metal single crystal is easily generated, and is required to be suitably selected so that dislocation and elastic stress induced by lattice mismatch are not easily generated.

2-dimensional nucleation energy barrier of the noble metal single crystal is determined by a material of the target noble metal single crystalline nanowire, an atomic structure of the low index planes of the target noble metal single crystalline nanowire, a material of the single crystalline substrate and a surface direction of the single crystalline substrate, or combination thereof.

As described above, the nonconductor or semiconductor single crystalline substrate is not particularly limited provided that it is a nonconductor or semiconductor forming an epitaxial relation with the target noble metal single crystalline nanowire, preferably with the low index plane of the noble metal single crystal and being chemically/thermally stable under the aforementioned heat treatment condition, but is actually selected from a single crystal of group 4 selected from a silicon single crystal, a germanium single crystal and silicon-germanium single crystal; a single crystal of groups 3-5 selected from a gallium-arsenide single crystal, an indium-phosphide single crystal and a gallium-phosphide single crystal; a single crystal of groups 2-6; a single crystal of group 4-6; a sapphire single crystal; and a silicon oxide single crystal, or a stacked substrate thereof.

In one example, a sapphire single crystal which is available in a low cost and is epitaxial to a single crystal of Pt, Au, Pd, AuPd, Ag and the like in a low index plane or a thermally stable plane is actually used.

Preferably, the precursor is platinum chloride, platinum bromide, platinum iodide or platinum fluoride, and the noble metal nanowire is a Pt nanowire.

In the case that the precursor is platinum chloride, platinum bromide, platinum iodide or platinum fluoride and the noble metal nanowire to be fabricated is a Pt nanowire, the temperature of the substrate is 850 to 1000° C., the pressure is 0.9 to 1.1 atm and the flow rate of the inert gas is 200 to 300 sccm.

More preferably, the precursor is platinum chloride, and a vertical Pt nanowire of which major axial direction is vertical to the surface of the substrate is formed by controlling the temperature of the precursor to 400 to 500° C. and a horizontal Pt nanowire of which major axial direction is horizontal to the surface of the substrate is formed by controlling the temperature of the precursor (platinum chloride) to 800 to 900° C.

At this time, the single crystalline substrate is preferably a sapphire single crystalline substrate having a C plane as a surface.

The present invention provides a single crystalline Pt nanowire using the aforementioned fabrication method. The Pt nanowire of the present invention is catalyst-free and template-free, has an epitaxial relation with the surface of the single crystalline substrate, has a major axis in vertical or horizontal relation with the substrate surface, and is a single crystal freely standing on the substrate surface without support.

More preferably, the Pt nanowire of the present invention is a single crystal having no 2-dimensional defect including twin and the major axis of the Pt nanowire is in [110] direction.

Hereinafter a second aspect of a fabrication method of a noble metal nanowire in accordance with the present invention will be described in detail.

The present invention provides a fabrication method of an Ag nanowire, wherein an Ag seed of a faceted shape, having an epitaxial relation with a single crystalline substrate and including a family of {001} plane and a family of {111} plane, is formed on the single crystalline substrate by thermally vaporizing Ag, a precursor, and transporting the vaporized Ag to the single crystalline substrate with an inert gas, and a single crystalline Ag nanowire with no 2-dimensional defect including twin and having a major axis parallel to a surface of the single crystalline substrate is fabricated from the Ag seed.

The Ag nanowire fabricated by growth of the Ag seed has an orientation with respect to the substrate, and the orientation means the orientation of the major axis of the nanowire fabricated on the substrate with respect to the surface of the substrate. Preferably, an Ag nanowire having a horizontal orientation to the surface of the substrate is fabricated.

Specifically, The Ag seed and the Ag nanowire are fabricated by placing the precursor in a front portion of a reactor and the single crystalline substrate in a rear portion of the reactor and flowing the inert gas from the front portion of the reactor to the rear portion of the reactor under a predetermined pressure.

To fabricate a nanowire having an orientation with respect to a substrate according to the technology (Korean patent application No. 2009-0028953) suggested by the present applicant, it is required to fabricate a seed having an epitaxial relation with the substrate and a faceted shape, control a main supplying mechanism of material supplied to the faceted seed, and control, to this end, a kind of the precursor, a material of the single crystalline substrate, a surface direction of the single crystalline substrate, a temperature of the precursor, a temperature of the single crystalline substrate, a flow rate of the inert gas, the pressure, or a combination thereof.

To fabricate an Ag nanowire having a horizontal orientation to the surface of the substrate, the precursor is preferably Ag, and the precursor includes Ag slug or Ag powder.

The temperature of the Ag precursor and the flow rate of the inert gas mainly have an influence on a nucleation driving force of the Ag seed and a growth driving force of the Ag seed on the substrate; the temperature of the Ag precursor, the flow rate of the inert gas the pressure and the temperature of the substrate mainly have an influence on a mechanism of the Ag material supply; and the temperature of the substrate and the pressure mainly have an influence on a surface phase of the Ag seed and the Ag nanowire.

The Ag precursor (the front portion of the reactor) is maintained at 780 to 800° C. and the single crystalline substrate (the rear portion of the reactor) is maintained at 650 to 700° C. The inert gas flows at 90 to 110 sccm from the front portion of the reactor to the rear portion of the reactor. And, the pressure is 5 to 7 torr. It is preferred to fabricate the Ag nanowire by performing heat treatment under the aforementioned condition.

When the temperature of the precursor, the temperature of the single crystalline substrate, the pressure and the flow rate of the inert gas are out of the condition described above, Ag not having a shape of the nanowire but having a shape of a rod or particle can be generated, an Ag nanowire not made of a single crystal but made of polycrystals can be generated, and there is a risk of losing a shape in that the surface of the Ag nanowire has a specific Ag crystal plane.

At this time, the single crystalline substrate is a nonconductive or semiconductive single crystalline substrate, of which material and surface direction have an epitaxial relation with a metal material constituting a metal seed to be fabricated.

The single crystal substrate is a surface of a nonconductive or semiconductive single crystal in which nucleation, particularly a 2-dimensional nucleation is easily generated upon generation of the metal seed to be fabricated, and is required to be suitably selected so that dislocation and elastic stress induced by lattice mismatch are not easily generated.

Preferably, the substrate has an epitaxial relation between a crystal plane that constitutes the surface of the substrate and a face selected from the group consisting of a family of {111} plane, a family of {110} plane and a family of {100} plane on the basis of a unique crystalline structure of the metal material constituting the metal nanowire to be fabricated.

More preferably, the single crystalline substrate is a nonconductive or semiconductive single crystalline substrate of which surface has an epitaxial relation with a face of a family of {100} plane on the basis of the unique crystalline structure of Ag, and most preferably, a SrTiO₃ single crystalline substrate with (001) surface to fabricate the Ag nanowire in which the major axes of the Ag nanowires having a horizontal orientation to the single crystalline substrate are perpendicular to each other.

As described above, the fabrication method of the present invention is the method of fabricating an Ag nanowire having a horizontal orientation to the substrate on the single crystalline substrate not by using a catalyst and an organic/inorganic template but by using Ag as the precursor, and has advantages that the process is simple and reproducible and a high purity nanowire with no impurities can be fabricated.

Also, it is possible to fabricate an Ag single crystalline nanowire, which has a horizontal orientation to the substrate surface and is independently and uniformly arranged in a specific direction without conglomeration.

The Ag seed of the faceted shape, having an epitaxial relation with the substrate and including a family of {001} plane and a family of {111} plane, is formed on the single crystalline substrate under the aforementioned condition of the temperature of the precursor, the temperature of the single crystalline substrate, the pressure and the flow rate of the inert gas, and the single crystalline Ag nanowire with no 2-dimensional defect including twin and having a major axis parallel to the surface of the single crystalline substrate is fabricated from the Ag seed under the aforementioned condition of the temperature of the precursor, the temperature of the single crystalline substrate, the pressure and the flow rate of the inert gas.

Preferably, the Ag seed of the faceted shape has a half-octahedron shape including four faces belonging to a family of {111} plane and one face belonging to a family of {001} plane, wherein the face belonging to a family of {001} plane has an epitaxial relation with the substrate and the four faces belonging to a family of {111} plane forms the surface of the seed.

The faceted Ag seed of the half-octahedron shape is mainly laterally grown in a direction parallel to the substrate as the material supplying mechanism is controlled in such an indirect supply that the precursor transported by the inert gas is supplied to the substrate and is then supplied to the seed by surface diffusion using the substrate surface as a transport path under the aforementioned condition of the temperature of the precursor, the temperature of the single crystalline substrate, the pressure and the flow rate of the inert gas, and thus a horizontal Ag nanowire having a major axis parallel to the substrate surface is fabricated.

At this time, the major axis of the Ag nanowire is in <110> direction, the Ag nanowire has two faces belonging to at least a family of {111} plane as a major axial surface, and one face belonging to a family of {001} plane forms an interface in a major axial direction together with the substrate, thereby fabricating the nanowire having an orientation parallel to the substrate.

The Ag nanowire of the present invention, which can be fabricated by the fabrication method described above, is an Ag nanowire of a twin free single crystal with no 2-dimensional defect including twin and of a faceted shape, and has two faces belonging to a family of {111} plane as the major axial surface, and one face belonging to a family of {001} plane forms an interface in the major axial direction together with the single crystalline substrate so that the Ag nanowire has an orientation in that the substrate and the major axis of the nanowire are parallel to each other.

The fact that Ag has a face centered cubic (FCC) structure is well known, and the nanowire shaped Ag single crystal with controlled surface direction and no 2-dimensional defect including twin also has the FCC structure

The major axis of the Ag nanowire is in <110> direction, and a minor axial section of the Ag is a triangular shape. The triangular shaped section is resulted from that the interface between the surface constituting the major axis and the substrate consists of a specific crystallographic plane: two faces belonging to a family of {111} plane constitute the surface of the major axis and one face belonging to a family of {001} plane forms the interface with the substrate, particularly the interface having an epitaxial relation with the substrate.

More preferably, in the Ag nanowire, of both end surfaces of the major axis consist of a face belonging to a family of {111} plane and the surface of the nanowire thus includes four faces belonging to a family of {111} plane, and one face belonging to a family of {001} plane forms the interface with the substrate.

The Ag nanowire is characterized as follows: the Ag nanowire is a pure single crystal with no 2-dimensional defect and has a horizontal orientation in that the surface of the substrate and a direction of the major axis are parallel to each other; the Ag nanowire has a crystallographically well defined surface; the Ag nanowire has a diameter (shortest diameter of the minor axis) of 100 to 400 nm and a major axial length of μm order; and the Ag nanowires having a horizontal orientation to the substrate have a predetermined arrangement to have horizontal or vertical relation with each other.

Preferably, the substrate is a SrTiO₃ single crystal with (100) plane, and two or more Ag nanowires having the orientation in that the substrate and the major axis of the nanowire are parallel have the major axes of which directions are perpendicular to each other.

### BRIEF DESCRIPTION OF THE DRAWINGS

FIG. 1 shows a Scanning Electron Microscope (SEM) photograph of a vertical Pt single crystal nanowire fabricated in Example 1 of the present invention.

FIG. 2 shows a SEM photograph of a horizontal Pt single crystalline nanowire fabricated in Example 2 of the present invention.

FIG. 3 is a photograph by a Transmission Electron Microscope (TEM) showing the Pt single crystalline nanowire fabricated in Example 1 of the present invention.

FIG. 4 is an image by High Resolution Transmission Electron Microscope (HRTEM) showing the Pt single crystalline nanowire fabricated in Example 1 of the present invention.

FIG. 5 shows a detection result using an Energy Dispersive Spectroscopy equipped in the TEM (TEM-EDS) of the Pt nanowire fabricated in Example 1 of the present invention.

FIG. 6 shows the result of an X-ray diffraction of the Pt nanowire fabricated in Example 1 of the present invention.

FIG. 7 is an X-ray diffraction pattern of the nanowire fabricated through Example 3.

FIG. 8 is a SEM photograph of the Ag nanowire fabricated through Example 3 according to heat treatment time.

FIG. 9 is a TEM photograph of the Ag nanowire fabricated through Example 3.

### DESCRIPTION OF SPECIFIC EMBODIMENTS

The advantages, features and aspects of the invention will become apparent from the following description of the embodiments with reference to the accompanying drawings, which is set forth hereinafter.

The present invention is characterized in that noble metal halide is used as a precursor and orientation of a noble metal single crystalline nanowire is controlled by controlling a temperature of the precursor, and the fabrication method will be described in detail using platinum chloride as the precursor as thermal decomposition and thermal vaporization characteristics of the noble metal halide are similar to each other.

### Example 1

A reactor is divided into a front portion and a rear portion which are provided with a heating element and a temperature controller, respectively. A tube in an inside of the reactor was made of quartz and had a size of 1 inch in diameter and 60 cm in length.

A boat type vessel of a high purity alumina material containing 0.03 g of PtCl₂ (Aldrich, #520632-1G, Tm=581° C.) therein was placed in the middle of the front portion of the reactor and a C-plane sapphire substrate was placed in the middle of the rear portion of the reactor.

Pressure in an inside of the quartz tube was maintained at 1 atm and argon gas was inputted the front portion of the reactor and was discharged from the rear portion of the reactor. The argon gas was controlled to flow at 300 sccm using a Mass Flow Controller (MFC).

Heat treatment was performed for 30 minutes with the temperature of the front portion of the reactor (alumina boat containing the precursor therein) being maintained at 400° C. and the rear portion of the reactor (sapphire substrate) being maintained at 1,000° C. to fabricate a Pt single crystalline nanowire having a vertical orientation to the substrate.

### Example 2

Fabrication of a Pt nanowire was performed under the same condition as Example 1 except for the temperature of the front portion of the reactor (the precursor), and the temperature of the front portion of the reactor (the precursor) was maintained not at 400° C. but 800° C. to fabricate a Pt single crystalline nanowire having a horizontal orientation to the substrate.

### Example 3

An Ag single crystalline nanowire having a horizontal orientation to a substrate was synthesized in a reactor by using Ag slug (Aldrich #373249-4.1G).

The reactor is divided into a front portion and a rear portion which are provided with a heating element and a temperature controller, respectively. A tube in an inside of the reactor was made of quartz and had a size of 1 inch in diameter and 60 cm in length.

A boat type crucible of a high purity alumina material containing 4.1 g of Ag slug (Aldrich, #373249-4.1G) therein was placed in the middle of the front portion of the reactor and a SrTiO₃ single crystalline substrate (0.3 cm×0.3 cm) having a (001) surface was placed in the middle of the rear portion of the reactor.

Argon gas is inputted into the front portion of the reactor and is discharged from the rear portion of the reactor, and the rear portion of the reactor is provided with a vacuum pump. The pressure in an inside of the quartz tube was maintained at 5 torr using the vacuum pump and Ar was controlled to flow at 100 sccm using a Mass Flow Controller (MFC).

Heat treatment was performed for 30 minutes with the temperature of the front portion of the reactor (alumina crucible containing Ag slug therein) being maintained at 790° C. and the rear portion of the reactor (SrTiO₃ substrate) being maintained at 670° C. to fabricate an Ag single crystalline nanowire.

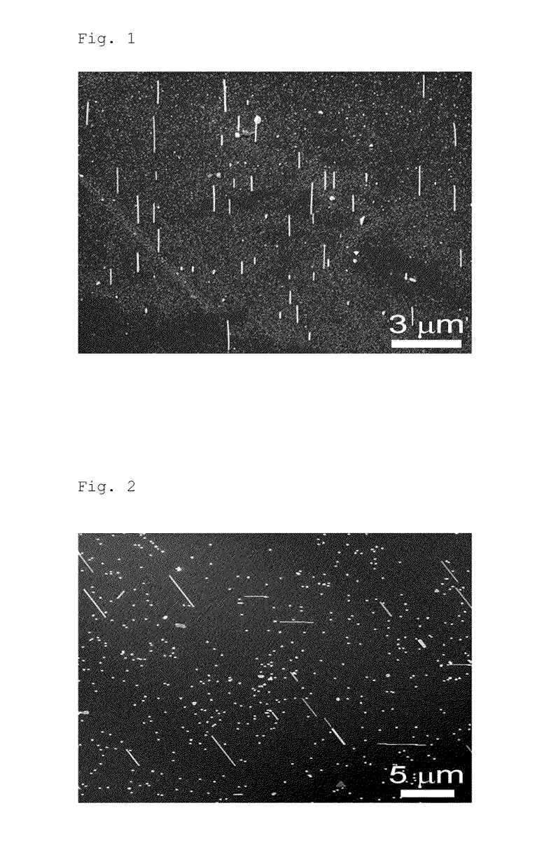

FIG. 1 shows a Scanning Electron Microscope (SEM) of the Pt single crystalline nanowire fabricated in Example 1. In FIG. 1, the substrate formed with the Pt nanowire was observed with being tilted by an angle of 45. From FIG. 1, it can be appreciated that a Pt single crystalline nanowire having an epitaxial relation with the substrate and grown vertically to the substrate surface is fabricated and a Pt single crystalline nanowire having very large aspect ratio, in which a mean diameter is 100 nm and mean length of the major axis is sever to tens μm, is fabricated.

FIG. 2 shows a SEM of the Pt single crystalline nanowire fabricated in Example 2. From FIG. 2, it can be appreciated that a Pt single crystalline nanowire having an epitaxial relation with the substrate and grown horizontally to the substrate surface is fabricated and a Pt single crystalline nanowire having very large aspect ratio, in which a mean diameter is 100 nm and mean length of the major axis is sever to tens μm, is fabricated similar to the Pt single crystalline nanowire of Example 1.

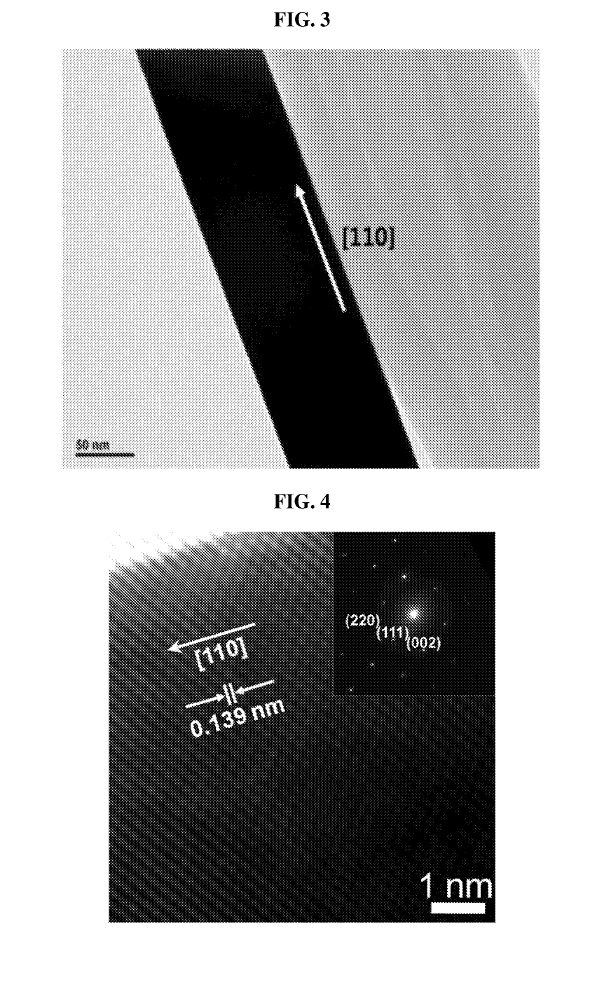

FIG. 3 is a dark field image by a Transmission Electron Microscope (TEM) showing the Pt single crystalline nanowire fabricated in Example 1; FIG. 4 is an image by High Resolution Transmission Electron Microscope (HRTEM) showing the Pt single crystalline nanowire fabricated in Example 1, in which an image inserted in the upper right portion of FIG. 4 is Selected Area Electron Diffraction pattern (SAED) of the nanowire. From FIGS. 3 and 4, it can be appreciated that a direction of the major axis of the fabricated Pt nanowire is [110] direction and the single nanowire is a perfect single crystal having no 2 dimensional defect including the twin and is also a single crystal having high crystallinity.

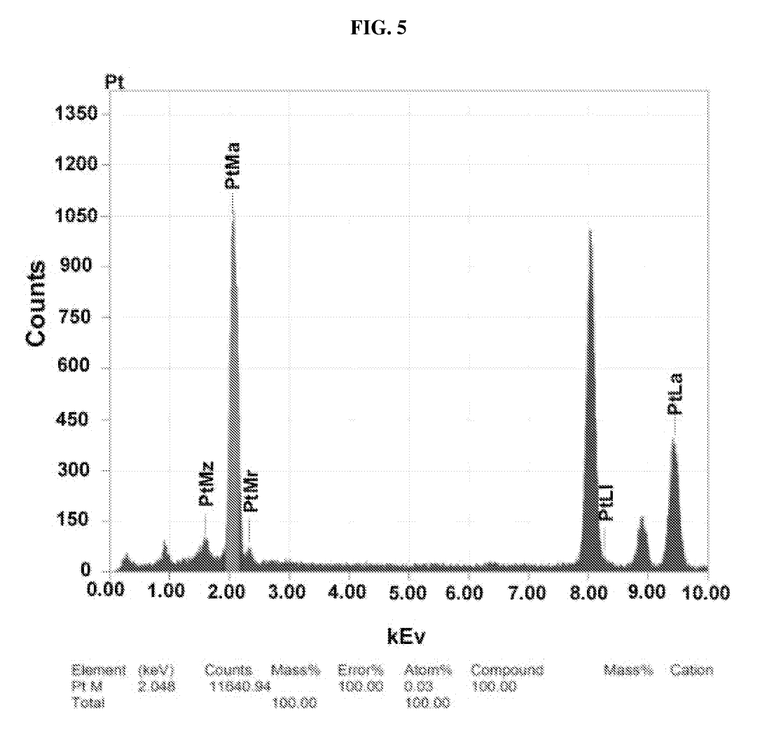

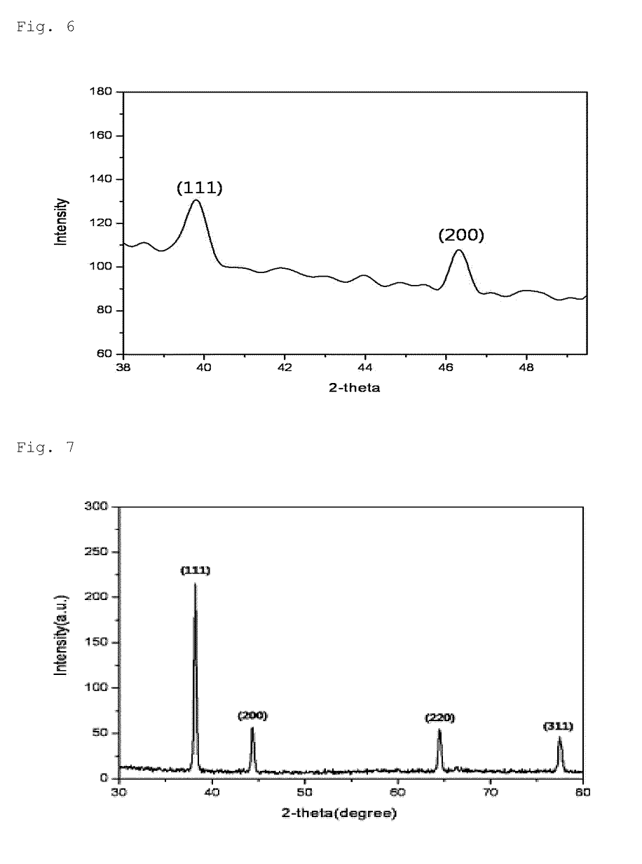

From FIG. 5 showing a detection result using an Energy Dispersive Spectroscopy equipped in the TEM (TEM-EDS), it can be appreciated that the fabricated nanowire is a pure Pt nanowire. It can also be appreciated that X-ray diffraction pattern of the fabricated nanowire agrees well with pure Pt (JCPDS card (04-0802)) through an X-ray diffraction result (FIG. 6).

From FIG. 7 showing an X-ray diffraction pattern of the nanowire fabricated through Example 3, it can be appreciated that X-ray diffraction peak of the fabricated nanowire agrees with Ag having a FCC structure (JCPDS 04-0783) and it is also appreciated that a crystalline Ag nanowire having a FCC structure is fabricated.

FIG. 8 is a SEM photograph of the Ag nanowire fabricated through Example 3 according to heat treatment time. It can be appreciated that a faceted Ag seed of a half-octahedron shape is formed as shown in FIG. 8A, the Ag seed is laterally grown in a direction parallel to the substrate formed as shown in FIGS. 8B and 8D, and a horizontal Ag nanowire of which direction of a major axis is parallel to the substrate surface, as shown in FIGS. 8C and 8E.

From a low resolution SEM photograph, it can be appreciated that the faceted Ag seed of a half-octahedron shape is laterally grown in a specific direction with respect to the substrate and thus there is a predetermined orientation between the Ag nanowires having a horizontal orientation to the substrate surface, and it can also be appreciated that Ag nanowires, e.g. Ag nanowire grown in a sequence of FIGS. 8A, 8B and 8C and Ag nanowire grown in a sequence of FIGS. 8A, 8D and 8E, of which direction of the major axes are perpendicular to each other are fabricated.

From FIGS. 8E, 8C and 8F, it can be appreciated that Ag nanowires having a diameter of 100 to 400 nm and a length of several μm is fabricated, a plurality of the fabricated nanowires has a uniform size and shape and are fabricated independently on the substrate without conglomeration, the fabricated nanowires have a faceted shape, and the faceted face is a very smooth and flat surface.

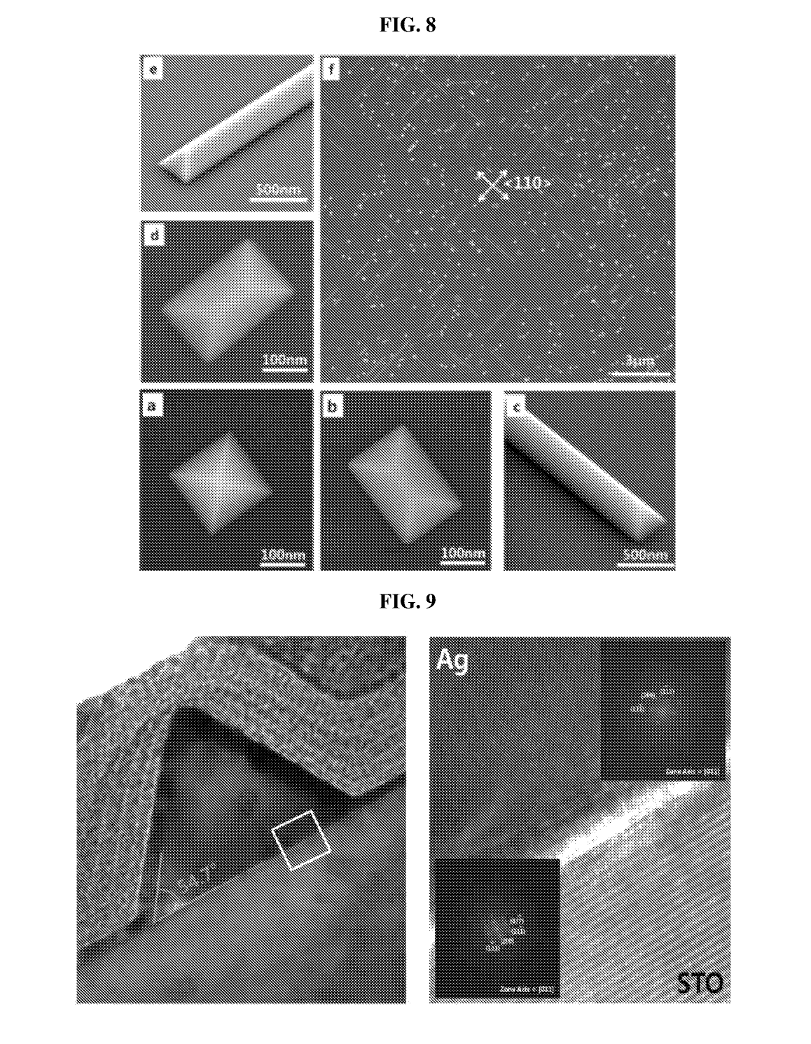

FIG. 9A is a TEM photograph of a section of the Ag nanowire fabricated through Example 3, FIG. 9B is a HRTEM photograph showing an interface between the Ag nanowire and the substrate indicated by a white rectangle, a figure inserted in upper right of FIG. 9B is SAED of the Ag nanowire, and a figure inserted in lower left of FIG. 9B is SAED of the single crystalline substrate.

From the sectional photograph of FIG. 9 and the SAED result of the Ag nanowire of FIG. 9, it can be appreciated that the single nanowire is a single crystal and has a FCC structure, which is agree with the X-ray diffraction pattern result of FIG. 7.

Also, from FIGS. 9A and 9B, it can be appreciated that a growth direction (major axis) of the Ag nanowire is [110] direction and the Ag nanowire is a pure single crystal with no 2-dimensional defect including twin.

From the result of HRTEM observation of FIG. 9B, it can be appreciated that {100} plane of the Ag nanowire forms an interface with the substrate to have an epitaxial relation with the substrate. From FIG. 9A, it can be appreciated that an interfacial angle between the {100} plane forming the interface with the substrate and the major axial surface is 54.7°. Also, from the SAED of FIG. 9B, it can be appreciated that the major axial surface of the Ag nanowire is formed of faces of a family of {111} plane.

From the TEM result of FIG. 9 and the SEM result and the angle between faceted surfaces of FIG. 8, it can be appreciated that the Ag seed of FIG. 8A having the surface including four faces belonging to a family of {111} plane and one face belonging to a family of {100} plane and having an epitaxial relation with the single crystalline substrate is fabricated, and the Ag seed is laterally grown in [011] direction to form the Ag nanowire having a horizontal orientation to the substrate while maintaining the surface structure formed of the four faces belonging to a family of {111} plane.

In accordance with the fabrication method of a noble metal nanowire of the present invention, by using noble metal halide as a precursor and controlling a temperature of the precursor, it is possible to fabricate a noble metal single crystalline nano wire of high purity and high crystallinity having an orientation to the surface of the substrate and it is also possible to fabricate a noble metal single crystalline nano wire of high purity and high crystallinity in bulk through a reproducible and simple fabrication process.

Also, in accordance with the present invention, by using noble metal halide as a precursor and simply controlling a temperature of the precursor, it is possible to control orientation of the noble metal single crystalline nanowire formed on the substrate, and is also possible to control so that a plurality of nanowires have the same orientation to the substrate surface.

The present invention provides a fabrication method of a plurality of noble metal single crystalline nanowires physically separated from each other and having a specific orientation to a substrate surface using noble metal halide as a precursor. Therefore, study for physical, optical and electromagnetic properties of a noble metal nanowire itself can be accelerated. Also, improvement in properties of an electric device, an optical device or a magnetic device using noble metal nanowire having excellent electric and thermal conductivity and being chemically stable can be expected. Further, improvement in control of detection property, sensitivity, precision and reproducibility of a spectroscope, a bio sensor, a sensor for detecting light, electricity, magnetism, heat or vibration or combination thereof using surface properties of the noble metal nanowire can be expected. Furthermore, it can be utilized as a MEMS structure and a 3-dimensional memory device using the vertical or horizontal arrangement to the surface of the single crystalline substrate.

The fabrication method of the present invention allows, by using a vapor transport process without use of a catalyst and an organic/inorganic template, fabrication of a high crystallinity, high shape and high purity single crystalline Ag nanowire which is present independently without conglomeration and has a horizontal orientation to the substrate, and has advantages that the process is simple, reproducible and mass producible.

By massively providing an Ag nanowire having a specific orientation with respect to the substrate and of which surface and shape are crystallographically well defined with a reproducible and simple process, it is possible to utilize the Ag nanowire to high sensitive sensors and high efficiency electric devices, optical devices or magnetic devices.

While the present invention has been described with respect to the specific embodiments, it will be apparent to those skilled in the art that various changes and modifications may be made without departing from the spirit and scope of the invention as defined in the following claims.

What is claimed is:

1. A fabrication method of a noble metal nanowire, wherein the noble metal nanowire having an epitaxial relation with a single crystalline substrate is fabricated on the single crystalline substrate using noble metal halide as a precursor by placing the precursor in a front portion of a reactor and the single crystalline substrate in a rear portion of the reactor and performing heat treatment in a condition that an inert gas flows from the front portion of the reactor to the rear portion of the reactor under a predetermined pressure, wherein a major axial direction of the noble metal nanowire with respect to a surface of the single crystalline substrate is controlled by controlling a temperature of the precursor.

2. The method of claim 1, wherein the noble metal halide is noble metal chloride, noble metal bromide, noble metal iodide or noble metal fluoride.

3. The method of claim 1, wherein the pressure is 0.9 to 1.1 atm, and a flow rate of the inert gas is 200 to 300 sccm.

4. The method of claim 3, wherein a temperature of the substrate is 0.4 to 0.95 Tm when assuming that a melting point (° C.) of the noble metal material of the noble metal nanowire to be fabricated is Tm.

5. The method of claim 4, wherein the temperature of the precursor is 0.6 to 0.9 times the lower temperature between a melting point (° C.) and a decomposition point (° C.) of the precursor and a vertical noble metal nanowire having the major axial direction vertical to the surface of the substrate is fabricated.

6. The method of claim 4, wherein the temperature of the precursor is 1.3 to 1.6 times the lower temperature between the melting point (° C.) and the decomposition point (° C.) of the precursor and a horizontal noble metal nanowire having the major axial direction horizontal to the surface of the substrate is fabricated.

7. The method of claim 1, wherein the substrate is a substrate which is epitaxial to a noble metal material of the noble metal nanowire to be fabricated.

8. The method of claim 4, wherein the precursor is platinum chloride, platinum bromide, platinum iodide or platinum fluoride, and the noble metal nanowire is a Pt nanowire.

9. The method of claim 8, wherein the temperature of the substrate is 850 to 1000° C.

10. The method of claim 9, wherein the precursor is platinum chloride, and a vertical Pt nanowire of which major axial direction is vertical to the surface of the substrate is formed by controlling the temperature of the precursor to 400 to 500° C.

11. The method of claim 9, wherein the precursor is platinum chloride, and a horizontal Pt nanowire of which major axial direction is horizontal to the surface of the substrate is formed by controlling the temperature of the precursor to 800 to 900° C.

12. A Pt nanowire of catalyst-free and template-free, having an epitaxial relation with the surface of the single crystalline substrate, having a major axis in vertical or horizontal relation with the substrate surface, and being a single crystal with no 2-dimensional defect including a twin and freely standing on the substrate surface without support.

13. A fabrication method of an Ag nanowire, wherein an Ag seed of a faceted shape, having an epitaxial relation with a single crystalline substrate and including a family of {001} plane and a family of {111} plane, is formed on the single crystalline substrate by thermally vaporizing Ag, a precursor, and transporting the vaporized Ag to the single crystalline substrate with an inert gas, and a single crystalline Ag nanowire with no 2-dimensional defect including twin and having a major axis parallel to a surface of the single crystalline substrate is fabricated from the Ag seed.

14. The method of claim 13, wherein the Ag seed and the Ag nanowire are fabricated by placing the precursor in a front portion of a reactor and the single crystalline substrate in a rear portion of the reactor and flowing the inert gas at 90 to 110 sccm from the front portion of the reactor to the rear portion of the reactor under 5 to 7 torr, and the precursor is maintained at 780 to 800° C. and the single crystalline substrate is maintained at 650 to 700° C.

15. The method of claim 13, wherein the Ag seed of a faceted shape is a half-octahedron which includes four planes belonging to a family of {111} plane and one plane belonging to a family of {001} plane.

16. The method of claim 15, wherein the Ag nanowire has a major axis extending in <110> direction and has two faces belonging to at least a family of {111} plane as a major axial surface, and one face belonging to a family of {001} plane forms an interface in a major axial direction together with the substrate, thereby fabricating the nanowire having an orientation parallel to the substrate.

17. The method of claim 14, wherein the substrate is a SrTiO₃ single crystal with (100) plane.

18. An Ag nanowire, which is a twin free single crystal with no 2-dimensional defect including twin and of a faceted shape, wherein the Ag nanowire has a major axis extending in <110> direction and has two faces belonging to a family of {111} plane as the major axial surface, and one face belonging to a family of {001} plane forms an interface in the major axial direction together with the single crystalline substrate so that the Ag nanowire has an orientation in that the substrate and the major axis of the nanowire are parallel to each other.

19. The Ag nanowire of claim 18, wherein the Ag nanowire has a minor axial section of a triangular shape.

20. The Ag nanowire of claim 18, wherein the substrate is a SrTiO₃ single crystal with (100) plane, and two or more Ag nanowires having the orientation in which the substrate and the major axis of the nanowire are parallel have the major axes of which directions are perpendicular to each other.
